(19) United States
(12) Patent Application Publication
(10) Pub. No.: US 2025/0228357 A1
(43) Pub. Date: Jul. 17, 2025

(54) WORKSTATION PLATFORM

(71) Applicant: Courtney MALE, West Beach (AU)

(72) Inventor: Courtney MALE, West Beach (AU)

(21) Appl. No.: 18/700,503

(22) PCT Filed: Oct. 14, 2022
(86) PCT No.: PCT/AU2022/051241

§ 371 Date: Apr. 11, 2024

(30) Foreign Application Priority Data
Oct. 14, 2021 (AU) 2021903306

(51) Int. Cl. A47B 13/08; A47B 21/03

(52) U.S. Cl. CPC A47B 13/081; A47B 2021/0321; A47B 2200/0066

(57) ABSTRACT

A workstation platform is disclosed. In one embodiment, the workstation platform comprises: a base member having an upper supporting surface including a first set of one or more grooves spanning at least partially across the supporting surface, and a first module including one or more downwardly depending tongues. Each tongue is located in interlocking relationship with a respective one of the one or more grooves to permit sliding adjustment of the first module on or relative to the supporting surface over a range.

### PRIORITY APPLICATION

This international patent application claims priority from Australian provisional patent application no. 2021903306 titled “Workstation Platform” filed on 14 Oct. 2021, the entire contents of which are herein incorporated by reference.

### FIELD

The invention relates to a workstation platform for supporting one or more electronic devices such as a laptop computer, a tablet, and associated peripheral devices. In a typical application, an embodiment may be used to support a laptop computer and its associated keyboard, mouse and/or controllers, such as gaming controllers.

### BACKGROUND

Personal computing devices, such as mini-PCs, laptop computers and tablets, have become integrated into every part of a person's life, from reading books (e.g., e-readers) to interacting with others on social media networks, to playing video games, as well as watching movies and television programming online. Consequently, personal computing devices are often used many hours a day by a user for varied applications.

In some cases, one or more devices are connected to a computing device so as to allow the user to control or interact with the computing device. For example, a computing device may be connected to a mouse and/or keyboard. In another example, when used for gaming, a computing device may be connected to one or more gaming controllers such as a HOTAS type controller for a flight simulator, a throttle type controller, a steering wheel type controller or the like. In some cases, the use of such controllers may render the connected arrangement impractical for use on the lap of a user when seated, or even on a desk or table having a surface which is not sized to support the connected arrangement. Hence, to set up interconnected arrangements a user must find a furniture item, such as a deck or table, having a suitable sized surface. However, even if such an item is located, once so used, the furniture item is not available for other uses. Furthermore, a desk or table may have a size and shape which is not well suited for different modes of use of the portable computing device. As one example, it could be that a table has a width which is well suited to laptop only type use, but which is not sufficiently wide to support one or more peripheral devices.

There exists a need for a workstation platform which is capable of supporting different configuration modes of a computing device. For example, at one time, the user may only need to use a laptop with an external keyboard and mouse in a compact space, while at other times the user may need to play video games using controllers which are required in addition to the laptop. Similarly, when using a portable computing device, the user may need to reposition the portable computing device at a comfortable distance from the user.

### SUMMARY

The following presents a simplified summary of one or more preferred embodiments of the present disclosure, in order to provide a basic understanding of such embodiments. This summary is not an extensive overview of all contemplated embodiments of the disclosure, and is intended neither to identify key or critical elements of all embodiments of the disclosure nor to delineate the scope of any or all embodiments of the disclosure. Its sole purpose is to present some concepts of one or more embodiments of the disclosure in a simplified form as a prelude to the more detailed description that is presented later.

In general terms, embodiments of the present disclosure provide a workstation platform having a base member to which one or more removable and/or interchangeable modules may be fitted in sliding interlocking relationship to vary a geometry and/or operating configuration or mode of the workstation platform.

According to a first aspect of an embodiment of the discloser, a workstation platform includes a base member configured to receive one or more removable and/or interchangeable modules in sliding interlocking relationship to allow adjustment of a lateral and/or forward-rearward extent of the removable and/or interchangeable modules, wherein said adjustment repositions an upper surface of the workstation platform to wherein said adjustment repositions an upper surface of the workstation platform to modify a positional relationship with a user.

According to another aspect of an embodiment of the present disclosure, there is provided a workstation platform, comprising:
a base member having an upper supporting surface including a first set of one or more grooves spanning at least partially across the supporting surface; and
a first module including one or more downwardly depending tongues, each tongue located in interlocking relationship with a respective one of the one or more grooves to permit sliding adjustment of the first module on or relative to the supporting surface over a range.

In certain embodiments, the one or more grooves of the base member are arranged in parallel relationship with each other and with a first axis of the base member. In this form, the first module may be slidingly adjusted in parallel alignment with the first axis of the base member when the one or more tongues are in interlocking relationship with a respective one of the one or more grooves.

Where used throughout this specification, references to the term “groove” denote a keyway, or a channel having an open top portion defined by spaced apart parallel edges which are coplanar planar with the supporting surface, and a depth dimension which depends downwardly from the open top portion. The grove may have a cross section profile which is shaped and or configured to receive one or more tongues so as to allow the tongue of the module to slide along it.

In an embodiment, at least an extent of an underside surface of the first module is in contacting relationship with the supporting surface during movement of the first module to maintain stability of the first module during movement.

The first axis may be a laterally extending axis of the base member. In such embodiments, when the first module is interlocking relationship with the base member, the workstation platform may be adjustable in width by moving the first module.

Alternatively, the first axis may be a depth extending axis of the base member. In such embodiments, when the first module is interlocking relationship with the base member, the workstation may be adjustable in depth by moving the first module.

In this respect, where used throughout this specification, references to the term “width” denote a lateral dimension of workstation platform, such as a dimension between the “sides” of the workstation platform. On the other hand, references to the term “depth” denote a dimension which is perpendicular to the width dimension and in the plane of the working surface, such as a dimension between the “front” of the workstation platform and the “rear” of the workstation platform.

In an embodiment, the first module includes a working surface for receiving a computer device and/or a peripheral device thereon. In such an embodiment, the one or more tongues may be attached to or formed integrally with an underside surface of the first module.

In an embodiment, the first module includes a user operative module and the one or more tongues are attached to or formed on an underside surface of the user operative module.

In certain embodiments, the one or more tongues are elongate tongues having a length which is substantially the same as the length of the corresponding grooves.

In certain embodiments, the base member includes a second set of one or more grooves spanning at least partially across the supporting surface of the base member in perpendicular relationship with the first set of one or more grooves. In such embodiments, the workstation platform may further include:
a second module including a second set of one or more downwardly depending tongues in interlocking relationship with a respective one of the one or more grooves of the second set of grooves to permit sliding adjustment of the second module on or relative to the supporting surface of the base member.

In certain embodiments, the one or more grooves of the second set of grooves are arranged in parallel relationship with each other and with a second axis of the base member. In this form, the second module may be slidingly adjusted in parallel alignment with the second axis of the base member when the one or more tongues are in interlocking relationship with a respective one of the one or more grooves.

In an embodiment, at least an extent of an underside surface of the first or second module is in contacting relationship with the supporting surface during sliding adjustment of the second module so as to reduce instability of the first module during that adjustment.

In another embodiment, at least an extent of an underside surface of the first or second module is in contacting relationship with a surface of the other module (that is, the second or first module) during sliding adjustment of the first or second module so as to reduce instability of the first module during that adjustment.

In another embodiment, an underside surface of the first or second module is in contacting relationship with a surface of the other module and the supporting surface during sliding adjustment to reduce instability of the first module during that adjustment.

In certain embodiments the base member may be simultaneously fitted with a first module and a second module such that the first module may be slidingly adjusted to vary the depth of the workstation and the second module may slidingly adjusted to vary the width of the workstation platform.

In certain embodiments, the base member may be simultaneously or separately fitted with a first module and/or a second module and/or a third module to establish or vary the operating configuration or mode of the workstation platform.

In an embodiment, when the base member is fitted with the first module and/or the second module, that or those modules may be removable for interchange with the third module to vary the operating configuration or mode of the workstation platform.

Accordingly, in certain embodiments, each groove of the first set of grooves intersects with each groove of the second set of grooves to form an arrangement of intersecting grooves. For example, the first set of grooves may at least partially span the supporting surface width-wise and the second set of grooves may at least partially span the supporting surface depth-wise in intersection with the first set of grooves. In such an arrangement, the first and/or second module may be selectively located in a respective set of grooves to provide for sliding adjustment in a required direction, that is either width-wise or depth-wise adjustment.

In certain embodiments, the first module and the second module may be adapted to be moved into an intermeshing relationship with each other. In such embodiments, when so moved, at least one of the first or second module is held in a “locked” position by the other module.

In certain embodiments, the workstation platform further includes:
a third module including one or more tongues in interlocking relationship with a respective groove of the first or second sets of grooves to permit sliding adjustment of the working surface of the third module on or relative to the supporting surface.

These and other embodiments of the invention will become more fully understood upon a review of the detailed description, which follows. These and other embodiments of the present invention will become apparent to those of ordinary skill in the art, upon reviewing the following description of specific, exemplary embodiments of the present invention in conjunction with the accompanying figures. While features of the present invention may be discussed relative to certain embodiments and figures below, all embodiments of the present invention can include one or more of the advantageous features discussed herein. In other words, while one or more embodiments may be discussed as having certain advantageous features, one or more of such features may also be used in accordance with the various embodiments of the invention discussed herein.

### DESCRIPTION OF THE DRAWINGS

FIG. 1 is a perspective view of a workstation platform according to an embodiment of the disclosure;

FIG. 2 is a perspective view of another workstation platform according to an embodiment of the disclosure;

FIG. 3 is a perspective view of another workstation platform according to an embodiment of the disclosure;

FIG. 4A and FIG. 4B are side perspective views of a base member suitable for use with a workstation platform according to an embodiment of the disclosure;

FIG. 5A, FIG. 5B and FIG. 5C illustrate, in cross section, alternative forms of one or more grooves of the base member shown in FIG. 4A and FIG. 4B;

FIG. 6A is a perspective view of a module suitable for use with a workstation platform according to an embodiment of the disclosure;

FIG. 6B is a bottom view of the module shown in FIG. 6A;

FIG. 7 is a top-side perspective view of another module according to another embodiment of the disclosure;

FIG. 8 is a side view of the module shown in FIG. 7;

FIG. 9 is a bottom perspective view of the module shown in FIG. 7;

FIG. 10A is a top-side perspective view of another module suitable for use with a workstation platform according to an embodiment of the disclosure;

FIG. 10B is a bottom perspective view of the module shown in FIG. 10A;

FIG. 11A is an exploded view of a workstation platform for use in a computing configuration according to an embodiment of the disclosure;

FIG. 11B is a front perspective view of the workstation platform shown in FIG. 11A;

FIG. 11C is a sectional view of the workstation platform shown in FIG. 11A;

FIG. 12 is a perspective view of the workstation platform of FIG. 11A shown configured for use in a computing configuration for a right handed user;

FIG. 13 is a perspective view of the workstation platform of FIG. 11A shown configured for use in a computing configuration for a left handed user;

FIG. 14A is an exploded view of a workstation platform for use in a gaming configuration according to an embodiment of the disclosure;

FIG. 14B is a bottom perspective view of the workstation platform shown in FIG. 14A;

FIG. 15A is a front perspective view of the workstation platform of FIG. 14A and FIG. 14A;

FIG. 15B a bottom perspective view of the workstation platform shown in FIG. 14A;

FIG. 16 is a perspective view of the workstation platform of FIG. 14A and FIG. 14B shown configured for use in a gaming configuration;

FIG. 17 is a perspective view of the workstation platform according to another embodiment of the present disclosure;

FIG. 18 is a perspective close-up view of a section of the workstation platform shown in FIG. 16;

FIG. 19 is a perspective view of a base module of the workstation platform of FIG. 16;

FIG. 20 is a perspective view of a channel and tongue configuration suitable for use with the base module of FIG. 19; and

FIG. 21 is an exploded a perspective view of the workstation platform of FIG. 17.

### DETAILED DESCRIPTION

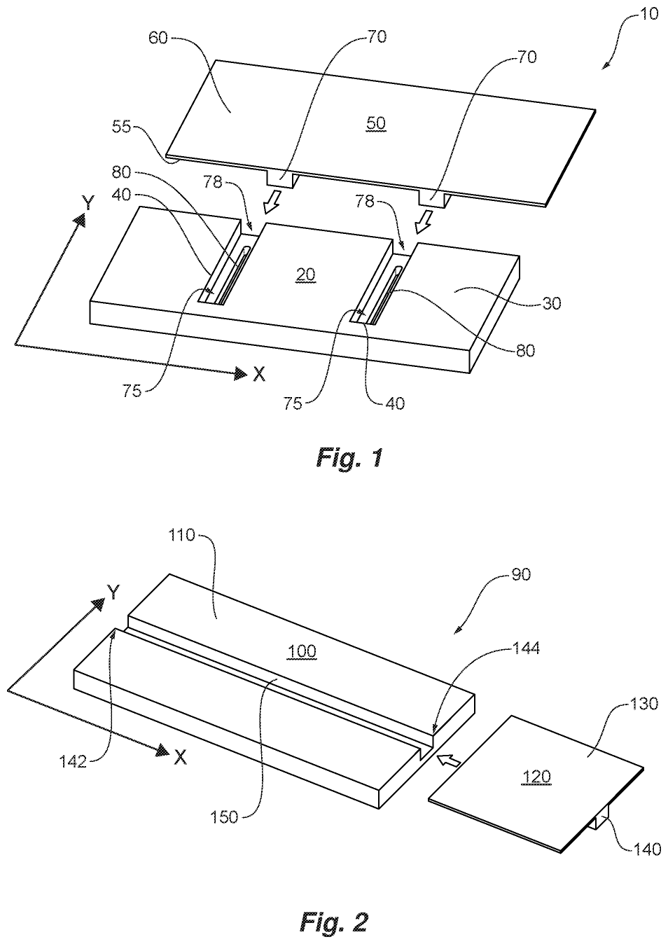

With reference to FIG. 1 there is shown a workstation platform 10 including a base member 20 and a first module 50. As shown, the base member 20 has a supporting surface 30 from which a pair of grooves 40 depend downwardly as they span at least partially across from the rear towards the front of the workstation platform 10. Although in the present case a pair of grooves 40 are shown, it is possible that in other embodiments one groove, or indeed more than two grooves may be provided.

In the present case, first module 50 includes a pair of downwardly tongues 70, shown here as a pair of elongate guides or rail elements, which depend downwardly from and extend along an underside surface 55 of the first module 50 in alignment with the pair of grooves 40 of the base member 20. In the illustrated embodiment, the first module 50 has working surface 60 for receiving a computer device and/or a peripheral device thereon, as will be described in more detail later.

The one or more tongues 70 of the first module 50 are attached to or otherwise formed to depend downwardly from the underside surface 55 of the first module 50. Although in the present case the first module 50 is shown as including a working surface 60 for receiving a computer device and/or a peripheral device thereon, it is possible that the first module 50 is a user operative module, such as a keyboard or joystick, and the one or more tongues 70 attach to are or formed on an underside surface of the user operative module.

In embodiments, each tongue 70 of the first module 50 is shaped and arranged to form an sliding interlocking relationship with a respective one of the one or more grooves 40 of the base member 20. When in such a relationship, sliding adjustment of the first module 50 is possible on or relative to the supporting surface 30 over a range. When so moved in this way, the interlocking relationship is such that the first module 50 is held in a retained relationship with the base member 20. This retained relationship prevents disassembly during normal sliding adjustment.

As shown in FIG. 1, each groove 40 of the pair of grooves 40 is aligned in parallel relationship with a Y axis of the base member 20. In the embodiment illustrated in FIG. 1, grooves 40 depend between a closed end 75 (shown located forwardly) and an open end 78 (shown located rearwardly). One advantage of including closed ends 75 is that they prevent unintended decoupling of first module 50 from the base member 20 as the first module 50 slides forwardly towards a user. The open ends 78, on the other hand, allow for the tongues 70 of the first module 70 to be received into the grooves 40 to form the above-described interlocking relationship therebetween.

In the present case, each groove 40 of the pair of grooves 40 includes an elongate depression 80 in the floor of the groove 40, such as a channel, for receiving a tooth (not shown) of a tongue 70 located in the groove 40 to form a keyed relationship therebetween which limits the extent of sliding adjustment rearwardly. Alternatively, a foam strip or other resilient material may be placed in the elongate depression 80 to provide a cushioning-type effect.

The first module 50 shown in FIG. 1 is a rectangular shaped member having a width and depth which is similar to the corresponding width and depth of the base member 20. However, in alternative embodiments it is possible that width and depth of the first module 50 may be different to that of the base member 20.

In the illustrated configuration, when the first module 50 is located in interlocking relationship with the base member 20, the working surface 60 of the first module 50 can be positioned so to substantially overlie the supporting surface 30 of the base member 20. When so positioned, the grooves 40 are at least partially concealed.

Working surface 60 may be a surface onto which a computer, peripheral device and/or books may be located or secured by suitable means. By suitable sliding adjustment of the first module 50, the relative position of a computer, peripheral device and/or books located and/or secured on or to the working surface 60 may be adjusted forwardly or rearwardly over an extent without requiring movement or repositioning of the base member 20. By such sliding adjustment, the computer, peripheral device and/or books may be moved towards or away from a user positioned in front of the workstation platform 10. In other words, the first module 50 shown here is slidably repositionable relative to or on the base member 20 when in an interlocking relationship therewith.

In the present case then, the tongues 70 and grooves 40 provide an interlocking relationship between the first module 50 and the base member 20 which permits the first module 50 to be slidably movable on the base member 20 in parallel alignment with a first axis, being the Y axis. In the present case, the slidable interlocking arrangement of the tongues 70 with corresponding grooves 40 thus permits a sliding adjustment which allows for repositioning the first module 50 by applying a force thereto which causes the first module 50 to slide forwardly or rearwardly, depending on the direction of the applied force. The extent to which the first module 50 may be adjusted relative to the base member 20 will depend on the maximum extent of the interlocking relationship formed therebetween which in turn depends on the combined total length extent of the grooves 40 and the tongues 70.

Before continuing further, although FIG. 1 shows a pair of grooves 40 aligned in parallel relationship with an axis (Y axis) of the base member, in another unillustrated form of the base member, the number of grooves can vary from one groove to multiple grooves. Similarly, the number of tongues of the module 50 could vary from one tongue to multiple tongues depending on the number of parallel grooves 40 on the base member 20. In another example (not shown in figures), the tongues 70 may be located to protrude more laterally.

With reference now to FIG. 2 there is shown a second embodiment of a workstation platform 90 according to another aspect of the disclosure.

The workstation platform 90 depicted in FIG. 2 comprises a base member 100 having a supporting surface 110. A groove 150 projects downwardly from and extends laterally across the supporting surface 110. A second module 120 includes a downwardly depending tongue, shown here as elongate tongue 140, which is shaped and arranged for interlocking relationship with the groove 150 to permit lateral sliding adjustment of the second module 120 relative to the supporting surface 110 of the base member 100.

In the example illustrated in FIG. 2, groove 150 depends between open ends 142, 144 disposed laterally of the base member 100. The use of an open-ended groove 150 allows the first module 120 to be located to position the tongue 140 for entry and/or exit from either of the sides of the base member 100 to form the interlocking relationship therewith.

When arranged in interlocking relationship, a working surface 130 of the second module 120 may be moved laterally outwardly or laterally inwardly relative to a user. In other words, the second module 120 shown here is slidably repositionable laterally (in other words, in a direction of the X axis) relative to or on the base member 100 when in an interlocking relationship therewith.

In view of the above it will be appreciated that second module 120 shown in FIG. 2 is adapted for sliding adjustment in parallel relationship with the X axis of the base member 100. In particular, when located in interlocking relationship with the base member 100, a position of the second module 120 is adjustable. In the present case, this adjustment involves repositioning the module 120 by applying a lateral force thereto which causes the module 120 to slide linearly rightwardly or leftwardly depending on the direction of the applied force. The extent to which the module 120 may be linearly adjusted relative to the base member 100 will depend on the maximum extent of the interlocking relationship formed therebetween which in turn depends on the combined total length extent of the groove 150 and the tongue 140.

Although FIG. 2 shows a single groove 150 arranged in parallel to the X axis of the base member 100, in another unillustrated form of the base member, the number of grooves in parallel to X axis can vary from one groove to multiple grooves. Similarly, the number of tongues 140 of the module 120 can vary from one tongue to multiple tongues which in turn depends on the number of parallel grooves on the base member 100. In another example, the tongue 140 may protrude a side of the module 120, rather than just from underneath the module 120.

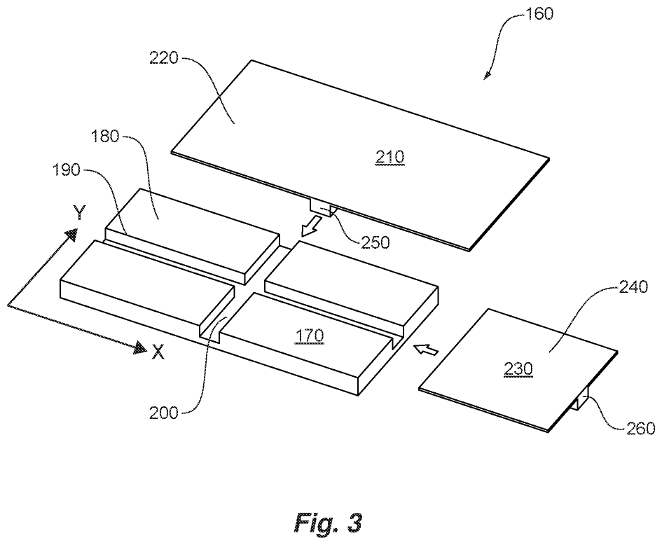

With reference now to FIG. 3 there is shown a workstation platform 160 according to another embodiment. The workstation platform 160 combines features similar to those described above with reference to FIG. 1 and FIG. 2.

In particular, the workstation platform 160 has a base member 170 having a supporting surface 180 including a pair of intersecting grooves 190, 200. First groove 190 is in parallel relationship with the Y axis of the base member 170 and second groove 200 is in parallel relationship with the X axis the base member 170. As is shown in FIG. 3, first groove 190 is perpendicular to second groove 200.

A first module 210 having an associated first working surface 220 and a second module 230 having an associated second working surface 240 may be separately located so as to form an interlocking relationship with the base member 170.

In this respect, the first module 210 shown here includes a tongue 250 which is positionable in interlocking relationship with groove 200 to permit sliding adjustment of a working surface 220 on or relative to the supporting surface 180 either forwardly or rearwardly (in other words inwardly or outwardly relative to the Y axis), whereas second module 230 includes a tongue 260 for forming an interlocking relationship with groove 190 to permit sliding adjustment of the second working surface 240 on or relative to the supporting surface 180 laterally.

The first module 210 and the second module 230 shown here are thus slidably repositionable with respect to the base member 170 when in interlocking relationships therewith. In this relationship, the tongue 250 and the groove 200 form an interlocking relationship between the first module 210 and the base member 170, whereas the tongue 260 and the groove 190 form an interlocking relationship between the second module 230 and the base member 170.

Although FIG. 3 shows a single groove 190 in parallel relationship with the X axis of the base member 170 and single groove 200 in parallel relationship with the Y axis of the base member 170, as will be described in relation to another embodiment below, the number of parallel grooves relative to the X axis and/or Y axis can vary from one groove to multiple grooves. Similarly, the number of tongues on each module can vary from one tongue to multiple tongues. Furthermore, the tongues may protrude from one of the sides of the module 210 or the module 230, rather than just from the underside of the respective support member.

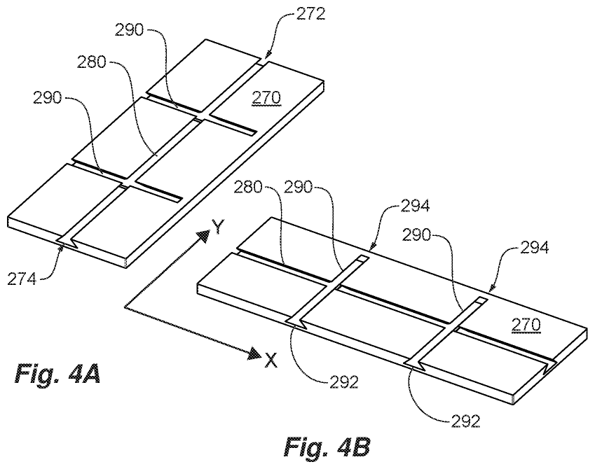

With now reference to FIG. 4A and 4B there is shown a side perspective view (FIG. 4A) and a front perspective view (FIG. 4B) of a base member 270 according to another aspect of an embodiment of the disclosure which is similar to the embodiment described above with reference to FIG. 3.

In embodiment depicted in FIG. 4A and FIG. 4B, the base member 270 includes a groove 280 depending between open ends 272, 274. Groove 280 is in parallel relationship with the X axis (ref. FIG. 4B) of the base member 270.

The base member 270 also includes a pair of grooves 290 in parallel relationship with the Y axis of the base member 270. Grooves 290 intersect with groove 280 of the base member 270 and are perpendicular thereto.

FIG. 4B shows a different view of the grooves 290 depending between a front open end 292 at one end of the base member 270 and a closed end 294 at the other end of the base member 270.

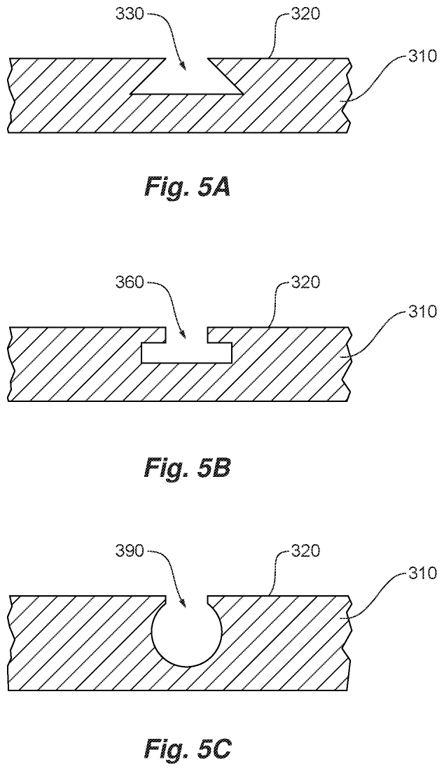

In the above-described base member 270, each groove 280, 290, has a cross sectional profile in the shape of a dove-tail type profile 330 of the type shown in FIG. 5A for forming an interlocked relationship with a tongue having a correspondingly shaped cross-sectional profile. In this case, dove-tail type profile 330 has a lateral extent which widens linearly as it depends downwardly from the supporting surface 320 of the illustrated portion of a base member 310.

However, it is to be appreciated that other cross-sectional profiles may be used. In this respect, FIGS. 5B and 5C show alternative non-limiting examples of other suitable cross-sectional profiles for the grooves. For example, FIG. 5B depicts a cross sectional profile 360 which is rectangular and which depends downwardly from a lip of the supporting surface 320 of the illustrated portion of a base member 310. FIG. 5C depicts a cross sectional profile 390 which is generally circular and which depends downwardly from a lip of the supporting surface 320 of the illustrated portion of a base member 310.

It will of course be appreciated by a skilled person that one or more grooves on the base member are not limited to a particular shape or design as illustrated in FIGS. 5A to 5C.

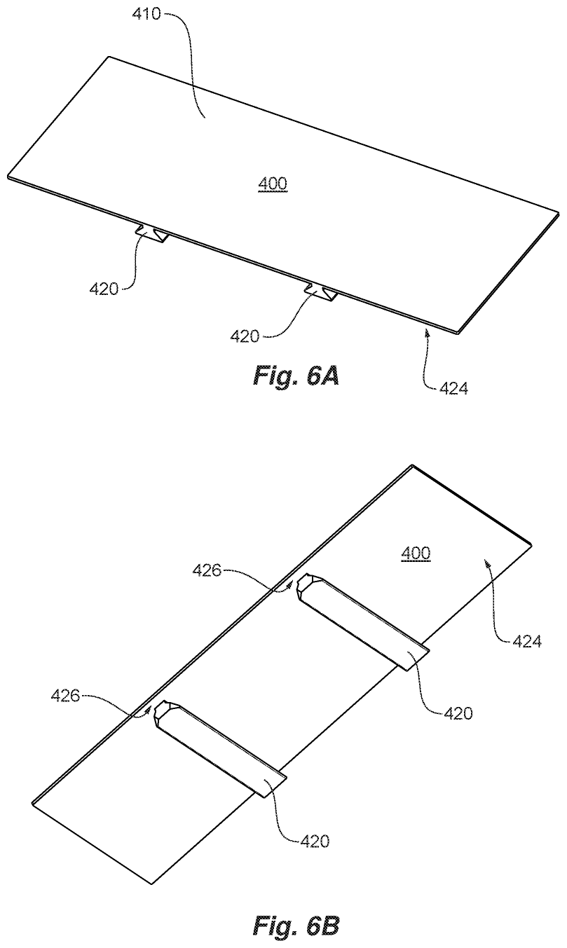

FIGS. 6A and 6B show perspective views of an example of a first module 400 suitable for use with the base member 270 shown in FIG. 4A and FIG. 4B. First module 400 has a working surface 410 onto which a computer, peripheral device and/or a gaming controller may be located or secured by suitable means. The configuration of the first module 400 is substantially the same as the first module 50 described above with reference to FIG. 1 with the exception that the first module 400 includes a pair of latterly spaced tongues, shown here as tongues 420, each of which projects downwardly from an underside surface 424 of the first module 400 and which each substantially extend between front and rear sides of the module 400 but for an offset 426 (shown with clarity in the rear perspective view shown in FIG. 6B) to accommodate closed end 294 (ref. FIG. 4B) of the respective groove 40.

Tongues 420 are shaped and arranged to form an interlocking relationship with corresponding grooves 290 of the base member 270 shown in FIGS. 4A and 4B. When so arranged, the module 400 is slidably movable on the base member 270. The interlocking relationship between the tongues 420 and corresponding grooves 290 thus permits sliding adjustment of the module 400 in parallel to the first axis Y of the base member 270.

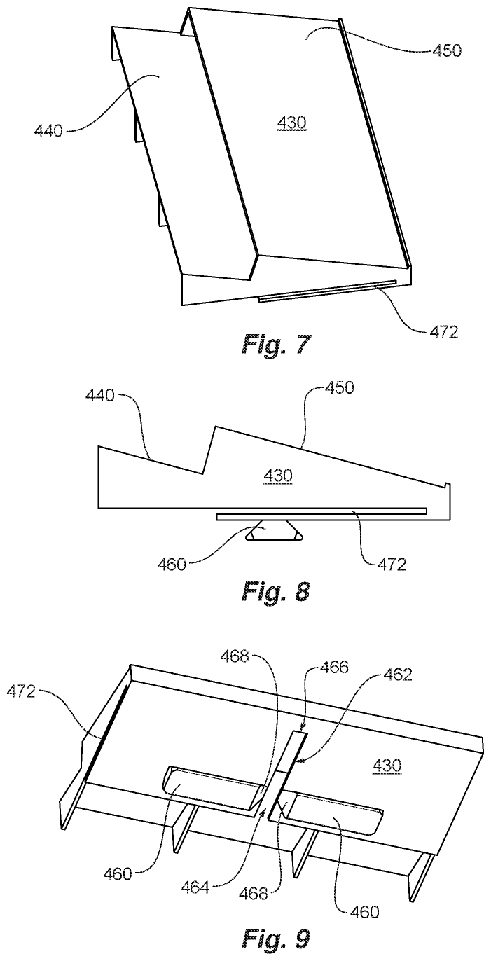

FIGS. 7 to 10 illustrate an example of a second module 430 suitable for use with the base member 270 shown in FIG. 4A and FIG. 4B simultaneously with the first module 400 shown in FIG. 6A and 6B.

Second module 430 shown here has a first working surface 440 for positioning, for example, a laptop computer thereon, and a second working surface 450 for positioning, for example, a keyboard thereon. A compartment or storage area is formed in a space between first working surface 440 and second working surface 450 such that when a laptop computer is placed/positioned on first working surface 440, at least a part of the laptop may be located in the compartment or storage area. In the present case, working surface 450 slants upwardly as it depends away from the front of module 430 so as to locate a keyboard placed on the working surface 450 in an inclined configuration for use.

Second module 430 includes pair of linearly spaced apart tongue members 460 arranged for interlocking relationship with groove 280 of base member 270 (ref. FIG. 4B).

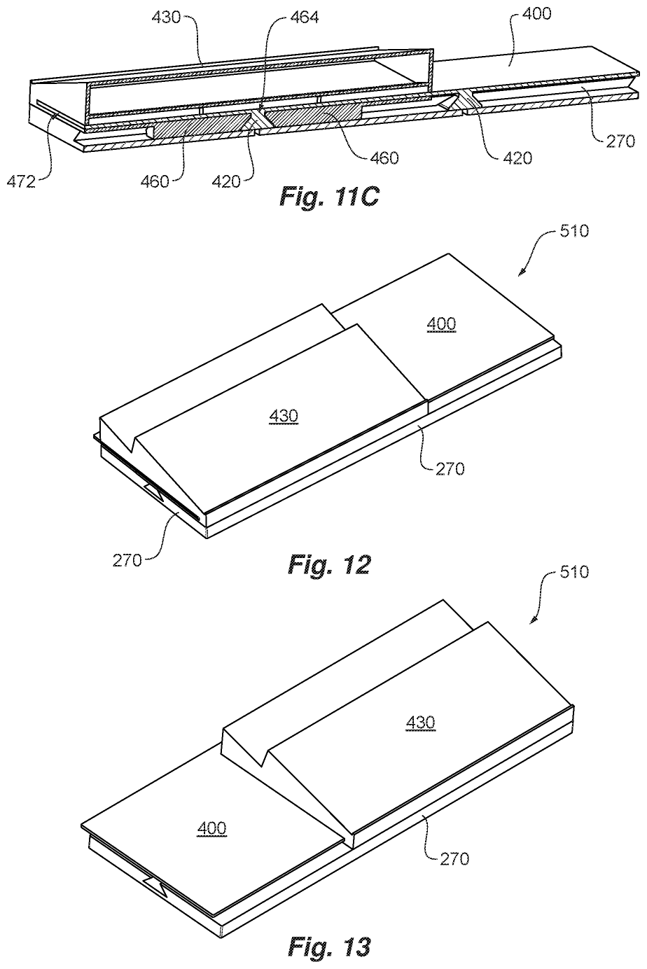

In the present case, tongue members 460 are disposed oppositely about a slot 462 so as to be spaced apart. Slot 462 extends between an open end 464 and a closed end 466 in perpendicular relationship with the tongue members 460 (shown with clarity in FIG. 8). Opposing faces 468 are angled so that the region between the faces 468 has a cross sectional profile which is substantially the same as that of groves 290. As best shown in FIG. 11A to 11C, when in interlocking relationship with the base member 270 (ref. FIG. 4B), the second module 430 may be slidingly adjusted so that the region between the faces 468 aligns with one of the grooves 290 (ref. FIG. 4B) of the base member 270. In this alignment, a tongue 420 of a first module 400 (ref. FIG. 6A) may pass through the slot 462 so that at least a portion of the working surface 220 of the first module 410 is received within a receiving region 472 (ref. FIG. 8) of the second module 430, as shown in FIG. 11B and 11C. When positioned in this way, the received tongue 420 of the first module 400 extends through gap 464 which has the effect of locking the second module 430 in its position. As shown in FIGS. 12 and 13, in the illustrated embodiment, two locked positions are possible.

The receiving region 472 shown here is a spacing between opposing planar surfaces of the second module 430.

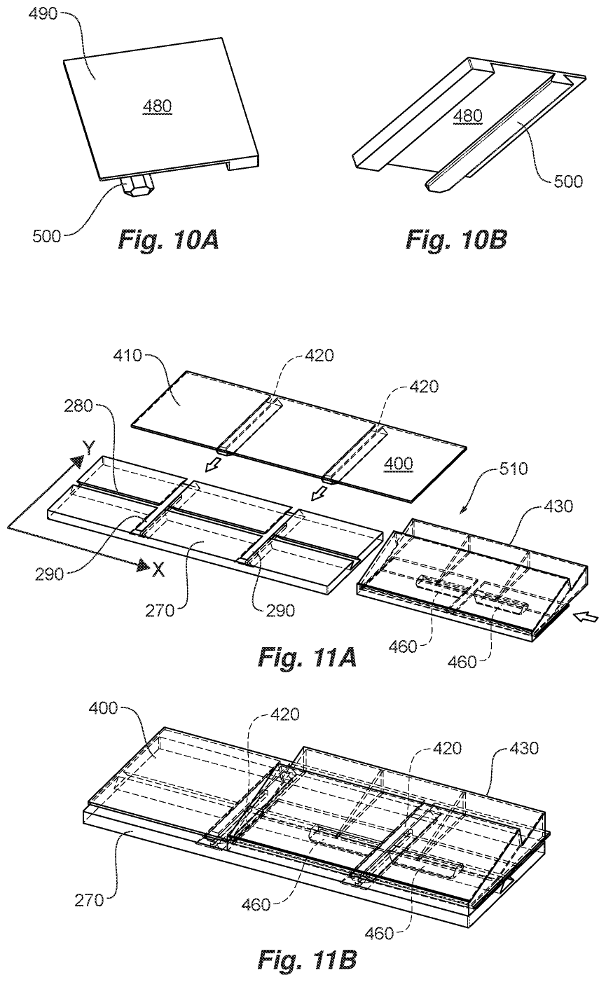

FIG. 10A and FIG. 10B are perspective views of another second module 480. The second module 480 shown here is a square shape wing-type member which projects laterally from the base member 270 when in an interlocking relationship therewith. Second module 480 includes a surface 490 onto which a gaming controller may be positioned or secured by suitable means. A tongue 500 projects laterally from the second module 480. This tongue 500 slides into the groove 280 of the base member 270 shown in FIGS. 4A and 4B.

Although FIG. 10A and FIG. 10B show a tongue 500 which protrudes from one of the sides of the module 480, in another unillustrated form of the module 480 the number of tongues may vary from one tongue to multiple tongues. In another example (not shown in Figures), the tongues are placed underneath the module 480, rather than protruding from one of the sides of the module 480.

The workstation platform as disclosed here is adjustable according to a user's preference and may also support multiple application modes according to the user's need as discussed in the following examples.

### EXAMPLE 1

### “Basic Mode” for providing an Adjustable Working Surface

In this mode, a workstation platform may be assembled using one base member such as base member 20 shown in FIG. 1, and one first module, such as first module 50 shown in FIG. 1.

As discussed above, the first module 50 is a rectangular shaped member having one or more tongues 70 in interlocking relationship with one or more grooves 40 of the base member 20. The first module 50 is slidably moveable on the base member 20 to permit sliding adjustment of the working surface 60 of the module 50. A working surface 60 is provided to allow a user to place a computer, peripheral device and/or books thereon.

A basic mode allows the user to reposition the computer, peripheral device and/or books placed on the working surface 60, at a comfortable forward-rear distance from the user. This is achieved by adjusting/sliding the working surface linearly inwardly or linearly outwardly on the base member by applying a force in the required direction.

### EXAMPLE 2

### “Computing Mode” for Supporting a Laptop and External Peripheral Devices

In another mode, referred to here as a “computing mode” an embodiment of the workstation platform may be assembled using, for example, base member 270, first module 400 and a second module 430 of the types shown in FIGS. 12 and 13.

Here, first module 400 is the same module as that described above with reference to FIGS. 6A and 6B. Second module 430 is the same as that described above with reference to FIGS. 7, 8 and 9. As shown, base module 270, first module 400 and second module 430 are assembled to form a workstation platform as described with reference to FIGS. 11A to 11C. In particular, second module 430, is positioned interlocking relationship with base member 270 and then slidably positioned so as to align space 464 (ref. FIG. 11C) with groove 290 (ref. FIG. 4B) of base member 270 to provide a keyway. When so positioned, the tongues 420 of first member 400 are slidably received by the grooves 290 and moved forwardly therealong. Depending on the groove 290 with which the space 464 is aligned, the respective tongue 420 in that groove 290 passes through the space 464 and locks the second module 430 in position to resist further adjustment laterally.

FIG. 12 shows a perspective view of a workstation platform 510 formed using the base member 270, the first module 400 and the second module 430 for use in a computing mode for a right-handed user. In this configuration, the second module 430 is in a locked position on the left side of the base member 270. On the other hand, FIG. 13 shows a perspective view of a workstation platform 510 formed using the base member 270, the first module 400 and the second module 430 for use in a computing mode for a left-handed user. In this configuration, the second module 430. In this configuration, the second module 430 is in a locked position on the right side of the base member 270.

### EXAMPLE 3

### Gaming Mode for Supporting a Computer Laptop, External Peripheral Devices and Gaming Controller(s)

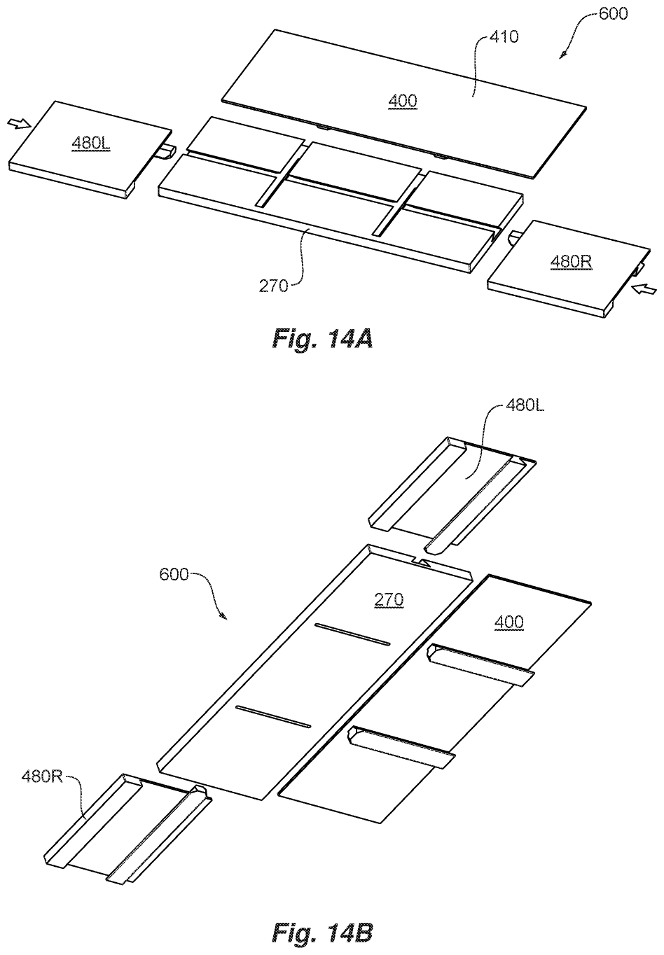

FIG. 14A and FIG. 14B show an embodiment 600 of the workstation platform assembled using a base member 270, first module 400, and seconds modules 480L, 480R. Second modules 480L, 480R are similar to the wing member 480 described above with reference to FIG. 10A and FIG. 10B.

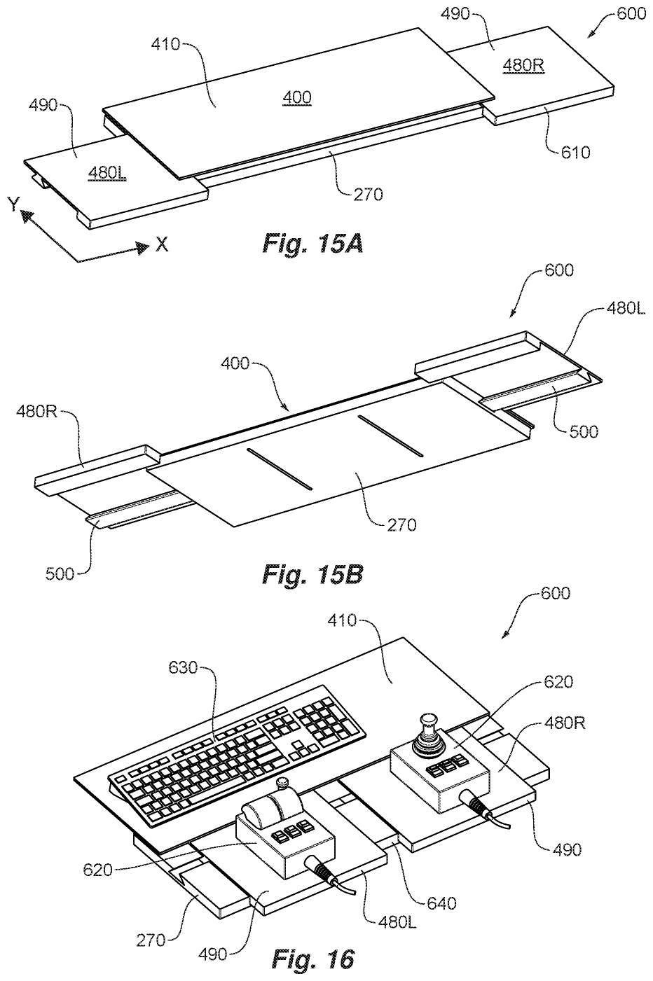

FIG. 15A, shows workstation platform 600 in an assembled form. As shown, second modules 480L, 480R includes downwardly depending tongues 600 which are slidably received into groove 280 (ref. FIG. 11A) of the base member 270 via each laterally disposed end of the groove 280 to form an interlocking relationship therewith. Once so positioned, second modules 480L, 480R may be slidably adjusted in position laterally inwardly or laterally inwardly over an extent to suit the positional requirements of the user depending on the position of the first module 400.

As shown in FIG. 15C, the tongues 420 (ref. FIG. 11A) of first module 400 are slidably received by the grooves 290 of the base module 270 to form an interlocking relationship therewith. In the present case, a front portion of the planar member 610 of the first module 400 overlies surface 490 of each second module 480L, 480R and is in contacting relationship therewith. In this arrangement, planar member 610 bears against surface 490 of each second module 480L, 480R to apply a friction force thereto which may help to maintain each second module 480L, 480R at a desired position.

In this configuration, gaming controllers may be placed on, or secured to, respective surfaces 490 of the second module 480L, 480R. A keyboard, mouse and/or a computer laptop may be located on the surface 410 of the first module 400. In other words, this configuration is similar to the basic mode configuration with an adjustable working surface except that it includes additional second modules 480L, 480R which project laterally from the base member 270 when in an interlocking relationship therewith.

FIG. 16 shows the workstation platform 610 in use, with the first module 400 offset rearwardly. In this position, the groove 280 of the base member 270 is not obstructed by the tongues 420 of the first module 400 and thus the second modules 480L, 480R may be adjusted in position along groove 280 according to the user's need. FIG. 16 also shows gaming controllers 620 located on the surfaces 490 and a keyboard 630 located on a working surface 410 of the first module 400. A computer laptop (not shown in the FIG. 16) may also be placed on the working surface 410 of the first module 400.

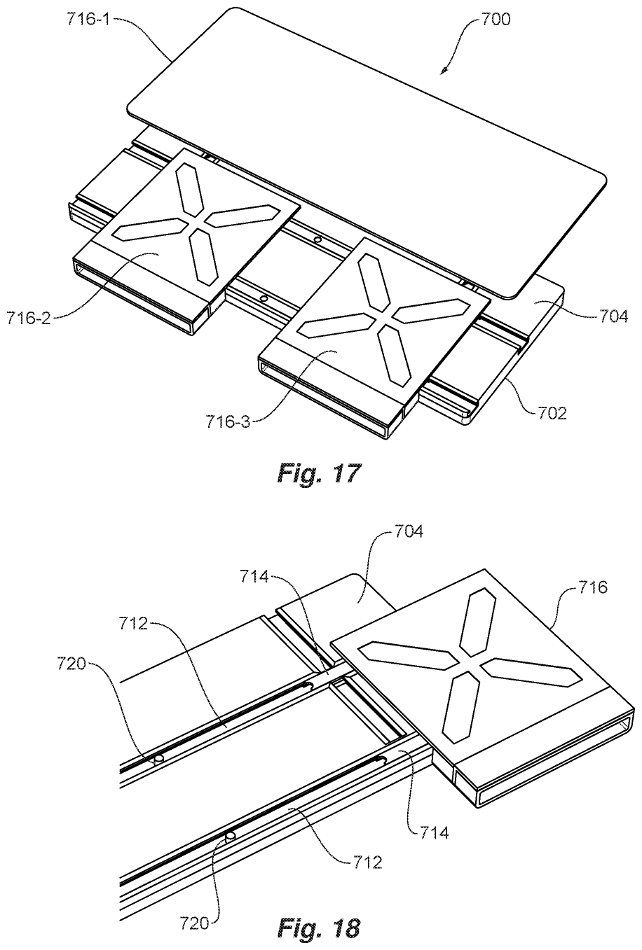

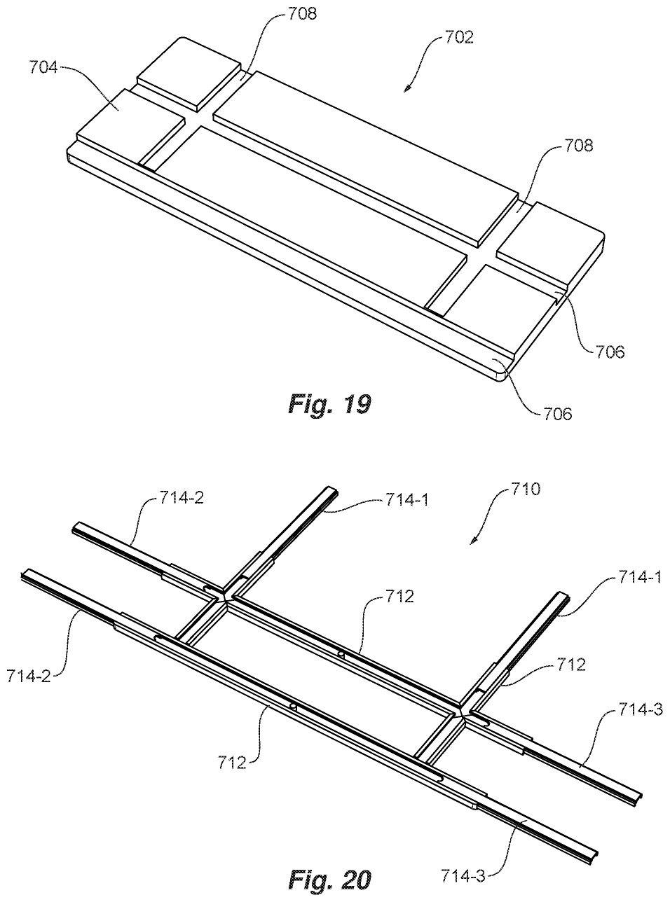

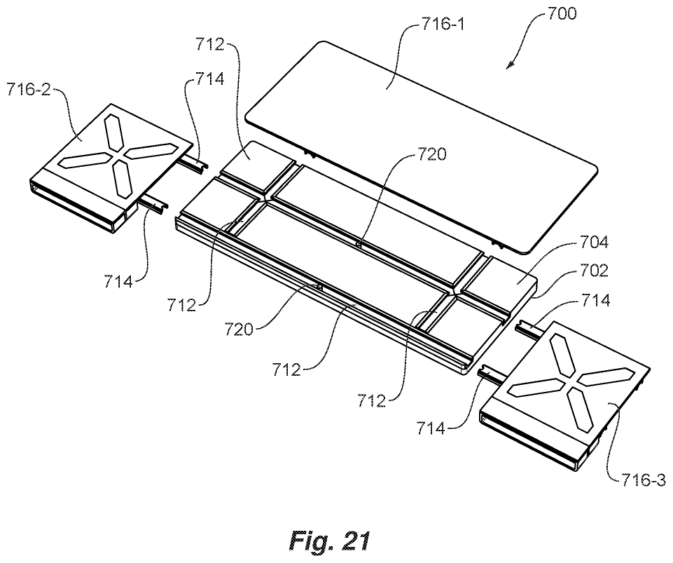

FIGS. 17 and 21 show a workstation platform 700 according to yet another embodiment. The workstation platform 700 has a base member 702 having a supporting surface 704. As shown in FIGS. 19, the base member 702 has a first pair of grooves 706 or slots which project downwardly and extend laterally across the base member 702. A second pair of grooves 708 is in perpendicular relationship with the first pair of grooves 706.

In the present case, a frame 712 (ref. FIGS. 18 and 20) is seated and secured in the grooves 706, 708 using suitable means to form a track arrangement or guide for receiving correspondingly shaped tongues 714-1, 714-2, 714-3 affixed to removable modules 716-1, 716-2, 716-3 respectively to permit a sliding interlocking engagement therebetween. In particular, when in sliding interlocking engagement the removable modules 716-2, 716-3 are able to slide laterally inwardly and outwardly relative to the base member 702 over an extent, and removable module 716-1 is able to slide forwardly and rearwardly relative to the base member 702 over an extent. Movement of any of removable modules 716-1, 716-2, 716-3 within its respective extent of movement modifies the positional relationship of the respective moved removable module 716-1, 716-2, 716-3 with a user.

Frame 712 and tongues 714 may be manufactured from suitable extrusions. As shown in FIG. 18, stops 720 are located in frame 712 to limit laterally inward travel of removable modules 716-2, 716-3 when the tongues 714-2, 714-3 affixed to removable modules 716-2, 716-3 respectively abut the stops 720.

The previous description of the disclosed implementations is provided to enable a person skilled in the art to make or use the disclosed implementations. Various modifications to these implementations will be readily apparent to those skilled in the art, and the principles defined herein may be applied to other implementations without departing from the scope of the disclosure. Thus, the present disclosure is not intended to be limited to the implementations shown herein but is to be accorded the widest scope possible consistent with the principles and novel features as defined by the succeeding claims.

For example, the number of parallel grooves of the base member varies from one groove to multiple grooves. In another example, the number of grooves does not need to be in parallel to either of the axis of the base member.

It will be understood that the terms “comprise” and “include” and any of their derivatives (e.g. comprises, comprising, includes, including) as used in this specification, and the claims that follow, is to be taken to be inclusive of features to which the term refers, and is not meant to exclude the presence of any additional features unless otherwise stated or implied.

The reference to any prior art in this specification is not, and should not be taken as an acknowledgement or any form of suggestion that such prior art forms part of the common general knowledge.

1. A workstation platform including a base member configured to receive one or more removable and/or interchangeable modules in sliding interlocking relationship to allow adjustment of a lateral and/or forward-rearward extent of the removable and/or interchangeable modules, wherein said adjustment repositions an upper surface of the workstation platform to modify a positional relationship with a user.

2. A workstation platform, comprising:
a base member having an upper supporting surface including a first set of one or more grooves spanning at least partially across the supporting surface; and
a first module including one or more downwardly depending tongues, each tongue located in interlocking relationship with a respective one of the one or more grooves to permit sliding adjustment of the first module on or relative to the supporting surface over a range.

3. The workstation platform according to claim 2 wherein the first set of one or more grooves of the base member comprise plural grooves arranged in parallel relationship with each other and with a first axis of the base member.

4. The workstation platform according to claim 2 wherein at least an extent of an underside surface of the first module is in contacting relationship with the supporting surface during movement of the first module to maintain stability of the first module during movement.

5. The workstation platform according to claim 2 wherein the first module includes a working surface for receiving a computer device and/or a peripheral device thereon.

6. The workstation platform according to claim 2 wherein the first module includes a user operative module.

7. The workstation platform according to claim 5 wherein the one or more tongues are attached to or formed integrally with an underside surface of the first module.

8. The workstation platform according to claim 1 wherein the base member includes a second set of one or more grooves spanning at least partially across the supporting surface of the base member in perpendicular relationship with the first set of one or more grooves, and wherein the adjustable workstation platform further includes:
a second module including a second set of one or more downwardly depending tongues for interlocking relationship with a respective one of the one or more grooves of the second set of grooves to permit sliding adjustment of the second module on or relative to the supporting surface of the base member.

9. The workstation platform according to claim 8 wherein the one or more grooves of the second set of grooves are arranged in parallel relationship with each other and with a second axis of the base member.

10. The workstation platform according to claim 8 wherein at least an extent of an underside surface of the first module is in contacting relationship with a surface of the second during sliding adjustment of the first or second module to reduce instability of the first module during that adjustment.

11. The workstation platform according to claim 8 wherein the first module and the second module are adapted to be moved into an intermeshing relationship with each other such that, when so moved, at least one of the first or second module is held in a locked position by the second or first module.

12. The workstation platform according to claim 2 wherein the base member includes a second set of one or more grooves spanning at least partially across the supporting surface of the base member in perpendicular relationship with the first set of one or more grooves, and wherein the adjustable workstation platform further includes:
a second module including a second set of one or more downwardly depending tongues for interlocking relationship with a respective one of the one or more grooves of the second set of grooves to permit sliding adjustment of the second module on or relative to the supporting surface of the base member.

13. The workstation platform according to claim 12 wherein the one or more grooves of the second set of grooves are arranged in parallel relationship with each other and with a second axis of the base member.

14. The workstation platform according to claim 12 wherein at least an extent of an underside surface of the first module is in contacting relationship with a surface of the second during sliding adjustment of the first or second module to reduce instability of the first module during that adjustment.

15. The workstation platform according to claim 12 wherein the first module and the second module are adapted to be moved into an intermeshing relationship with each other such that, when so moved, at least one of the first or second module is held in a locked position by the second or first module.

16. A method of forming a workstation platform, comprising:
providing a base member having an upper supporting surface including a first set of one or more grooves spanning at least partially across the supporting surface;
providing a first module including one or more downwardly depending tongues; and
locating each tongue in interlocking relationship with a respective one of the one or more grooves to permit sliding adjustment of the first module on or relative to the supporting surface over a range.

17. The method according to claim 16, further comprising:
providing in the base member, a second set of one or more grooves spanning at least partially across the supporting surface of the base member in perpendicular relationship with the first set of one or more grooves;
providing a second module including a second set of one or more downwardly depending tongues; and
locating the second set of one or more downwardly depending tongues in interlocking relationship with a respective one of the one or more grooves of the second set of grooves to permit sliding adjustment of the second module on or relative to the supporting surface of the base member.
